(19) United States
(12) Patent Application Publication
(10) Pub. No.: US 2013/0255515 A1
(43) Pub. Date: Oct. 3, 2013

(54) POSITIVE-WORKING LITHOGRAPHIC PRINTING PLATE PRECURSORS

(71) Applicants: Celin Savariar-Hauck, Badenhausen (DE); Gerhard Hauck, Badenhausen (DE); Rene Ullrich, Trebitz (DE); Dietmar Frank, Osterode (DE)

(72) Inventors: Celin Savariar-Hauck, Badenhausen (DE); Gerhard Hauck, Badenhausen (DE); Rene Ullrich, Trebitz (DE); Dietmar Frank, Osterode (DE)

(21) Appl. No.: 13/430,798

(22) Filed: Mar. 27, 2012

(51) Int. Cl. B41N 1/08; G03F 7/20; G03F 7/004

(52) U.S. Cl. 101/453; 430/270.1; 430/283.1; 430/302

(57) ABSTRACT

A positive-working multi-layer lithographic printing plate precursor has an inner imageable layer disposed over a substrate. This inner imageable layer comprises one or more first polymeric binders that are present in a total amount of at least 50 weight % and up to and including 97 weight %, based on total inner imageable layer dry weight. The precursor also has an ink-receptive outer imageable layer disposed over the inner imageable layer and this ink-receptive outer imageable layer comprises one or more second polymeric binders that are different than the first polymeric binder. Each of the one or more first polymeric binders has a weight average molecular weight of at least 200,000 and can also have a polydispersity of at least 4.

### FIELD OF THE INVENTION

This invention relates to multi-layer positive-working lithographic printing plate precursors that can then be used by the method of this invention to provide lithographic printing plates with improved properties such as improved run length.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imageable elements useful to prepare lithographic printing plates typically comprise one or more imageable layers applied over the hydrophilic surface of a substrate. The imageable layers include one or more radiation-sensitive components that can be dispersed in a suitable binder. Alternatively, the radiation-sensitive component can also be the binder material. Following imaging, either the imaged regions or the non-imaged regions of the imageable layer are removed by a suitable developer, revealing the underlying hydrophilic surface of the substrate. If the imaged regions are removed, the element is considered as positive-working. Conversely, if the non-imaged regions are removed, the element is considered as negative-working. In each instance, the regions of the imageable layer (that is, the image areas) that remain are ink-receptive, and the regions of the hydrophilic surface revealed by the developing process accept water and aqueous solutions, typically a fountain solution, and repel ink.

Direct digital or thermal imaging has become increasingly important in the printing industry because of their stability to ambient light. The imageable elements for the preparation of lithographic printing plates have been designed to be sensitive to heat or infrared radiation and can be exposed using thermal heads of more usually, infrared laser diodes that image in response to signals from a digital copy of the image in a computer a platesetter. This “computer-to-plate” technology has generally replaced the former technology where masking films were used to image the elements.

These imaging techniques require the use of alkaline developers to remove exposed (positive-working) or non-exposed (negative-working) regions of the imaged layer(s). In some instances of positive-working lithographic printing plate precursors that are designed for IR imaging, compositions comprising infrared radiation-sensitive absorbing compounds (such as IR dyes) inhibits and other dissolution inhibitors make the coating insoluble in alkaline developers and soluble only in the IR-exposed regions.

It is well known that the use of poly(vinyl acetal) resins as described in U.S. Pat. No. 7,544,462 (Levanon et al.) and U.S. Patent Application Publication 2011/0059399 (Levanon et al.) in positive-working lithographic printing plate precursors provide good run length, but there is still a need to improve resistance to solvents such as those used in lithographic developing and printing. Many efforts have been made to improve the solvent resistance in the lithographic art, for example, by introducing bulky ester groups on the vinyl alcohol units of the poly(vinyl acetal) backbone. This effort can improve solvent resistance. However, this can reduce run length in the resulting lithographic printing plate. Thus, it is difficult to provide both run length and solvent resistance because what can provide one property can damage the other.

A high solvent resistance, for example for resole resins, is required to enable the lithographic printing plate to have bakeability. It has also been found that poly(vinyl acetal) resins are difficult to make consistently with the same desired properties. In other words, there can be batch to batch non-uniformity and this requires that each batch of resins be pre-tested before they are used to produce lithographic printing plate precursors.

Workers in the lithographic industry have spend many hours trying to make polymers that will provide the desired properties of good image quality, photo speed, solvent resistance, bakeability under mild conditions, and improved run length in positive-working lithographic printing plate precursors.

U.S. Pat. No. 7,824,840 (Patel et al.) describes copolymers for use in 2-layer positive-working lithographic printing plate precursors. The primary polymeric binder has an acid number of at least 40 and includes recurring units derived from one or more N-alkoxymethyl (alkyl)acrylamides or alkoxymethyl (alkyl)acrylates, recurring units derived from one or more ethylenically unsaturated polymerizable monomers having a pendant cyano group such as acrylonitrile, and recurring units having one or more carboxy, sulfonic acid, or phosphate groups.

U.S. Patent Application Publication 2011/0097666 (Savariar-Hauck et al.) describes polymers similar to those described in U.S. Pat. No. 7,824,840 (noted above), but the acidic recurring units in the polymers have 1H-tetrazole groups that provide even more solvent resistance and bakeability.

Despite these advances in the art, there remains a need to improve run length in positive-working lithographic printing plate precursors without a loss in solvent resistance.

### SUMMARY OF THE INVENTION

The present invention provides a positive-working lithographic printing plate precursor comprising a substrate having a hydrophilic surface, and two or more layers disposed on the substrate, at least one of the layers comprising an infrared radiation absorber,

the two or more layers comprising:

an inner imageable layer disposed over the substrate, which inner imageable layer comprises one or more first polymeric binders that are present in a total amount of at least 50 weight % and up to and including 97 weight %, based on total inner imageable layer dry weight, and

an ink-receptive outer imageable layer disposed over the inner imageable layer, which ink-receptive outer imageable layer comprises one or more second polymeric binders that are different than the first polymeric binder,

wherein each of the first one or more polymeric binders has a weight average molecular weight of at least 200,000.

In some precursors of this invention:

1) each of the one or more first polymeric binders has a weight average molecular weight of at least 200,000 and up to and including 600,000, and a polydispersity of at least 4 and up to and including 10.5,

2) each of one or more first polymeric binders has an acid number of at least 40 meq KOH/g of polymer, and at least one of the first polymeric binders comprises recurring units randomly distributed along the polymer chain, that are derived from one or more of the following groups of ethylenically unsaturated polymerizable monomers:
a) N-alkoxymethyl (meth)acrylamides or alkoxymethyl (alkyl)acrylates,
b) ethylenically unsaturated polymerizable monomers having pendant cyano groups,
c) ethylenically unsaturated polymerizable monomers having pendant 1H-tetrazole groups,
d) ethylenically unsaturated polymerizable monomers having one or more carboxy, sulfo, or phospho groups, and
e) ethylenically unsaturated polymerizable monomers represented by Structures (D1) through (D4):

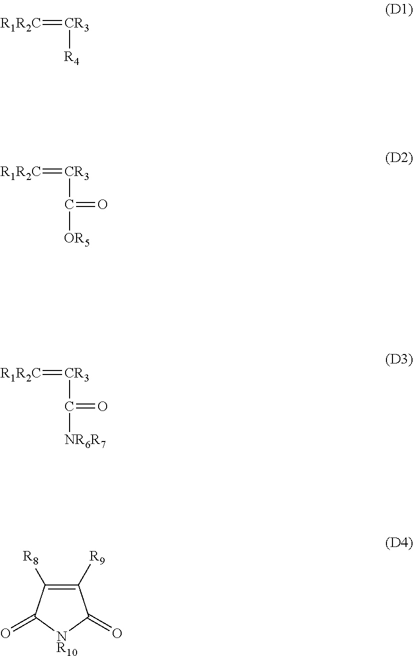

wherein R₁ and R₂ are independently hydrogen or alkyl, alkenyl, phenyl, halo, alkoxy, or acyloxy groups, or R₁ and R₂ together can form a cyclic ring with the carbon atom to which they are attached,

R₃ and R₄ are independently hydrogen or alkyl, phenyl, or halo groups,

R₅ is an alkyl, alkenyl, cycloalkyl, or phenyl group, R₆ through R₉ are independently hydrogen or alkyl, alkenyl, phenyl, halo, alkoxy, acyl, or acyloxy groups, and

R₁₀ is hydrogen or an alkyl, phenyl, or hydroxy group,

3) the ink-receptive outer imageable layer comprises at least two second polymeric binders, at least one of which is an acidic polyurethane and at least another of which is a carboxy-functionalized phenolic resin,

4) the infrared radiation absorber is present in an amount of at least 0.5 weight % and up to and including 25 weight %,

5) the infrared radiation absorber is present only in the inner imageable layer,

6) when the inner imageable layer and outer imageable layer are exposed to infrared radiation, they become more removable in a developer having a pH of 12.5 or less than before exposure to infrared radiation, and

7) the substrate is an aluminum-containing substrate.

This invention also provides a method for making a lithographic printing plate, comprising:

imagewise exposing the positive-working lithographic printing plate precursor of this invention (for example, as described above) to infrared radiation, thereby forming an imaged precursor having exposed and non-exposed regions in the inner imageable layer and the ink-receptive outer imageable layer, and

processing the imaged precursor to remove the exposed regions of the inner imageable layer and the ink-receptive outer imageable layer and to form a lithographic printing plate.

Moreover, this invention provides a lithographic printing plate comprising a substrate having a hydrophilic surface, and two or more layers disposed on the substrate, at least one of the layers comprising an infrared radiation absorber,

the two or more layers comprising:

an inner imageable layer disposed over the substrate, which inner imageable layer comprises one or more first polymeric binders that are present in a total amount of at least 50 weight % and up to and including 97 weight %, based on total inner imageable layer dry weight, and

an ink-receptive outer imageable layer disposed over the inner imageable layer, which ink-receptive outer imageable layer comprises one or more second polymeric binders that are different than the first polymeric binder, wherein each of the one or more first polymeric binders has a weight average molecular weight of at least 200,000 and a polydispersity of at least 4, and

wherein the inner imageable layer and the ink-receptive outer imageable layer are present on the substrate only in non-exposed regions while the inner imageable layer and the ink-receptive outer imageable layer have been removed in exposed regions to uncover the hydrophilic surface of the substrate.

It has been found that certain polymers that are designed to have both specific molecular weight and in some embodiments, a specific polydispersity, provide multi-layer positive-working lithographic printing plate precursors with improved run length while maintaining desired solvent resistance. These useful polymers are incorporated into the lower (inner) imageable layer that does not form the printing surface. Their desired properties are designed into the polymers by judicious choice of preparatory reaction conditions and reactants for their synthesis, such as solvent, temperature, polymerizable monomers, and polymerization initiator concentration. It has been found, for example, that copolymerization of a mixture of monomers including an N-hydroxy or alkoxy methyl (meth)acrylamides, depending on the reaction conditions, tends to form branched polymers having the desired high molecular weight and high polydispersity.

Generally, polymers with very high molecular weight can cause problems in lithographic printing plates such as “peeling type” development and poor image resolution. The term “peeling type” development refers to the coating peeling off or lifting off as multiple particles rather than dissolving away in the development. This effect can cause problems with redeposition of lifted off material on the rollers in the processor apparatus. The benefit of using polymers with high polydispersity is that the high molecular weight fractions contribute to high run length and the low molecular weight fractions maintain good developability without losing their solvent resistant properties.

Further details of the advantages of the present invention will become evident from considering the description and workings examples provided below.

### DETAILED DESCRIPTION OF THE INVENTION

### Definitions

Unless the context indicates otherwise, when used herein, the terms “lithographic printing plate precursor”, “positive-working lithographic printing plate precursor”, “precursor”, and “multi-layer positive-working lithographic printing plate precursor” are meant to be references to embodiments of the present invention.

The term “support” is used herein to refer to an aluminum-containing material (web, sheet, foil, or other form) that is then treated to prepare a “substrate” that refers to a hydrophilic article upon which various layers are coated or applied in a suitable manner.

In addition, unless the context indicates otherwise, the various components described herein such as the components of the various layers in the precursors or the developer (processing) solutions used in the method of this invention, refer to one or more of those components. Thus, the singular form “a”, “an”, or “the” is not necessarily meant to refer to only a single component but can also include the plural referents.

Terms that are not explicitly defined in the present application are to be understood to have meaning that is commonly accepted by those skilled in the art. If the construction of a term would render it meaningless or essentially meaningless in this context, the term's definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

Unless otherwise indicated, percentages refer to percents by dry weight of a composition or layer, or % solids of a solution.

As used herein, the term “infrared radiation absorber” refers to compounds that are sensitive to wavelengths of radiation beginning at 700 nm and higher, and that can convert photons into heat within the layer in which they are disposed.

As used herein, the term “infrared” refers to radiation having a λₘₐₓ of at least 700 nm and higher. In most instances, the term “infrared” is used to refer to the “near-infrared” region of the electromagnetic spectrum that is defined herein to be at least 700 nm and up to and including 1400 nm.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, for example, in reference to the first polymeric binders that have a different definition, the terms “polymer” and “polymeric” refer to high and low molecular weight polymers including oligomers and includes homopolymers and copolymers.

The term “copolymer” refers to polymers that are derived from two or more different monomers, in random order along the polymer backbone. That is, they comprise recurring units having different chemical structures in a random order along the polymer chain, unless block copolymers are specified.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Substrates

The two or more layers present in the positive-working lithographic printing plate precursors are disposed on a suitable substrate. In many embodiments, the inner imageable layer and ink-receptive outer imageable layer are the only layers and they are disposed directly (contiguous) on the substrate.

The substrate generally has a hydrophilic surface that is more hydrophilic than the applied imageable layer(s) on the imaging side. The substrate comprises a support that can be composed of any material that is conventionally used to prepare precursors such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports can be modified on one or both flat surfaces with a “subbing” layer to enhance hydrophilicity, or paper supports can be similarly coated to enhance planarity. Examples of subbing layer materials include but are not limited to, alkoxysilanes, amino-propyltriethoxysilanes, glycidioxypropyltriethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

One useful substrate is composed of an aluminum support that can be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid or phosphoric acid anodized aluminum support that provides a hydrophilic surface for lithographic printing.

Sulfuric acid anodization of the aluminum support generally provides an oxide weight (coverage) on the surface of at least 1.5 g/m² and up to and including 5 g/m² and more typically at least 3 g/m² and up to and including 4.3 g/m². Phosphoric acid anodization generally provides an oxide weight on the surface of from at least 1.5 g/m² and up to and including 5 g/m² and more typically at least 1 g/m² and up to and including 3 g/m².

An interlayer can be formed by post-treatment of the aluminum support with, for example, a silicate, dextrin, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support can be treated with a phosphate solution that can further contain an inorganic fluoride (PF). The aluminum support can be electrochemically-grained, sulfuric acid-anodized, and treated with PVPA or PF using known procedures to improve surface hydrophilicity.

A substrate an also comprise a grained and sulfuric acid anodized aluminum-containing support that has also been treated with an alkaline or acidic pore-widening solution to provide its outer surface with columnar pores so that the diameter of the columnar pores at their outermost surface is at least 90% of the average diameter of the columnar pores. This substrate can further comprise a hydrophilic layer disposed directly on the grained, sulfuric acid anodized and treated aluminum-containing support, and the hydrophilic layer comprises a non-crosslinked hydrophilic polymer having carboxylic acid side chains. Further details of such substrates and methods for providing them are provided in copending and commonly assigned U.S. Ser. No. 13/221,936 (filed Aug. 31, 2011 by Hayashi) that is incorporated herein by reference.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate can be coated with antistatic agents, slipping layers, or a matte layer to improve handling and “feel” of the precursor.

### Inner Imageable Layer

The inner imageable layer is disposed between the ink-receptive outer imageable layer and the substrate. Typically, it is disposed directly on the substrate (including any hydrophilic coatings as described above). The inner imageable layer comprises one or more first polymeric binders that are generally more removable using a suitable processing solution (for example a pH 12.5 or less processing solution or developer) than before exposure to infrared radiation. In addition, the first polymeric binder is usually insoluble in the solvent(s) used to coat the ink-receptive outer imageable layer so that the ink-receptive outer imageable layer can be coated over the inner imageable layer without dissolving the inner imageable layer. Mixtures of these first polymeric binders can be used if desired in the inner imageable layer. Such first polymeric binders are generally present in the inner imageable layer in an amount of at least 50 weight %, and generally at least 80 weight % and up to and including 97 weight % based on the total dry inner imageable layer weight.

Each of the one or more first polymeric binders has a weight average molecular weight (M_{w}) of at least 200,000 and up to and including 600,000, and typically a weight average molecular weight of at least 300,000 and up to and including 450,000, as measured by gel permeation chromatography (polystyrene standards).

In addition, each of the one or more first polymeric binders can have a polydispersity of at least 4 and up to and including 10.5, or typically of at least 4.5 and up to and including 8. The polydispersity is defined as the ratio of the weight average polymer molecular weight (M_{w}) to the number average polymer molecular weight (Mₙ), that is, M_{w}/Mₙ.

Moreover, each of one or more first polymeric binders has an acid number of at least 40 meq KOH/g of polymer, and typically an acid number of at least 65 meq KOH/g of polymer and up to and including 130 meq KOH/g of polymer, as measured by titration.

At least one of the first polymeric binders comprises recurring units randomly distributed along the polymer chain, which are derived from one or more of the following groups of ethylenically unsaturated polymerizable monomers:

a) N-alkoxymethyl (meth)acrylamides or alkoxymethyl (alkyl)acrylates, wherein “alkyl” includes substituted and unsubstituted methyl and ethyl groups,

b) ethylenically unsaturated polymerizable monomers having pendant cyano groups,

c) ethylenically unsaturated polymerizable monomers having pendant 1H-tetrazole groups,

d) ethylenically unsaturated polymerizable monomers having one or more carboxy, sulfo, or phospho groups, and

e) ethylenically unsaturated polymerizable monomers represented by Structures (D1) through (D4):

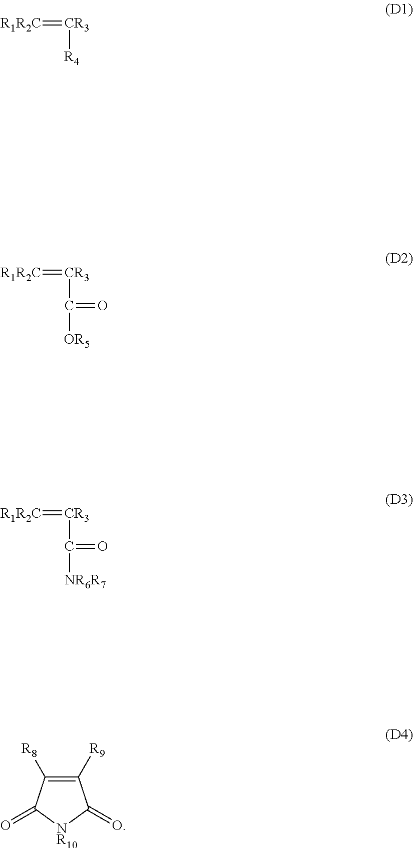

The R₁ and R₂ groups in Structures (D1) through (D3) are independently hydrogen or substituted or unsubstituted, linear or branched alkyl (1 to 20 carbon atoms), substituted or unsubstituted alkenyl (2 to 20 carbon atoms), substituted or unsubstituted phenyl, halo, alkoxy (1 to 20 carbon atoms), acyl, or acyloxy groups, or R₁ and R₂ together can form a substituted or unsubstituted cyclic ring (at least 5 atoms forming the ring) with the carbon atom to which they are attached. The optional substituents on these groups would be readily apparent to one skilled in the art. Typically, the R₁ and R₂ groups are independently hydrogen, or a substituted or unsubstituted alkyl group having 1 to 4 carbon atoms (such as methyl, ethyl, iso-propyl, and t-butyl groups).

The R₃ and R₄ groups in Structures (D1) through (D3) are independently hydrogen or substituted or unsubstituted alkyl (1 to 20 carbon atoms), substituted or unsubstituted phenyl, or halo groups. Typically, the R₃ and R₄ groups are independently substituted or unsubstituted alkyl groups having 1 to 6 carbon atoms, substituted or unsubstituted phenyl groups, and chloro groups.

In Structure (D2), R₅ is a substituted or unsubstituted alkyl (1 to 20 carbon atoms), alkenyl (2 to 20 carbon atoms), cycloalkyl (5 to 10 carbon atoms in the ring), or a phenyl group. Typically, R₅ is a methyl, ethyl, or benzyl group.

The R₆ through R₉ groups in Structures (D3) and (D4) are independently hydrogen or substituted or unsubstituted alkyl (1 to 20 carbon atoms), alkenyl (2 to 20 carbon atoms), alkoxy (1 to 20 carbon atoms), or phenyl groups, halo, acyl, or acyloxy groups. Typically, R₆ through R₉ are independently hydrogen, methyl, or ethyl groups.

In Structure (D4), R₁₀ is hydrogen a substituted or unsubstituted alkyl (1 to 20 carbon atoms) or phenyl group, or a hydroxy group. Typically, R₁₀ is a substituted or unsubstituted phenyl group.

Ethylenically unsaturated polymerizable monomers that can provide recurring units of group a) include but are not limited to, N-methoxymethyl methacrylamide, N-iso-propoxymethyl methacrylamide, N-n-butoxymethyl methacrylamide, N-ethoxymethyl acrylamide, N-methoxymethyl acrylamide, iso-propoxymethyl methacrylate, N-cyclohexoxymethyl methacrylamide, phenoxymethyl methacrylate, N-isobutoxymethacrylamide, N-t-butoxymethacrylamide, N-ethylhexyloxymethacrylamide, N-methoxymethyl acrylate, N-cyclohexyloxymethyl acrylamide, phenoxymethyl acrylate, and N-ethoxymethyl acrylate

Ethylenically unsaturated polymerizable monomers that can provide recurring units of group b) include but are not limited to, methacrylonitrile, acrylonitrile, cyanostyrenes such as p-cyanostyrene, and cyano(meth)acrylates such as ethyl-2-cyanomethyl methacrylate.

Ethylenically unsaturated polymerizable monomers that can provide recurring units of group c) include but are not limited to, ethylenically unsaturated polymerizable monomers that have a pendant 1H-tetrazole group and one or more ethylenically unsaturated free radical polymerizable groups. In an alkaline solution, the tetrazole groups lose a hydrogen atom at the 1-position, as illustrated in the following Equation (1):

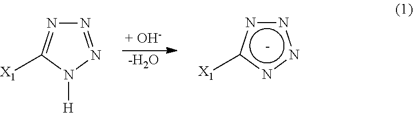

wherein X₁ represents the remainder of a non-polymeric molecule or a linking group connected to a polymer backbone. In many embodiments (but not all), the 1H-tetrazole is connected at its 5-position to a nitrogen. The 1H-tetrazole groups can be attached to the ethylenically unsaturated groups that form part of the polymeric binder backbone through a linking group L comprising a —C(═O)—NR¹—, —NR¹—(C═O)—NR²—, —S—, —OCO(═O)—, or —CH═N— group, or a combination thereof. Particularly useful linking groups include —C(═O)—NR¹— and —NR¹—(C═O)—NR²—. The noted linking groups can be directly attached to the backbone or attached through an organic group having up to 30 atoms in the linking chain.

Examples of useful ethylenically unsaturated polymerizable monomers of this type are identified as A₁ through A₈ in TABLE A of U.S. Patent Application Publication 2009/0142695 (Baumann et al.) that is incorporated herein by reference.

Alternatively, the 1H-tetrazole groups can be introduced into the polymeric binder after it has formed. For example, the 1H-tetrazole groups can be introduced into polymers already having reactive functionalities for the amino group in 1H-tetrazole-5-amine. Examples of such reactive polymers have reactive isocyanato groups, (meth)acrylate groups, epoxy groups, nitrile groups, halomethyl group, cyclic anhydride of dicarboxylic acids or reactive aldehyde or ketone groups as shown above. Typical examples of such reactive polymers are those derived from isocyanatoethyl methacrylate, glycidyl methacrylate, (meth)acrylonitrile, chloromethylated styrene, maleic acid anhydride, and methyl vinyl ketone. For example, (meth)acrylate functionalized polymers that can react with 1H-tetrazole-5-amine are typically made by introduction of the (meth)acrylic functionality into a polymer, for example, by reaction of —OH groups with (meth)acrylic acid chloride or by introducing β-halogeno-substituted propionic acid groups followed by dehydrohalogenation.

Ethylenically unsaturated polymerizable monomers that can provide recurring units of group d) include but are not limited to, (meth)acrylic acids, carboxystyrenes, N-carboxyphenyl (meth)acrylamides, and (meth)acryloylalkyl phosphates.

Ethylenically unsaturated polymerizable monomers that can provide recurring units of group e) include but are not limited to, styrenes, methacrylates, methacrylamides, N-phenylmaleimides, iso-propyl(meth)acrylamides, and maleic anhydride, (meth)acrylates, and (meth)acrylamides. Other possibilities would be readily apparent to a worker skilled in the art.

In the first polymeric binders, the amount of recurring units derived from one or more of the a) group of ethylenically unsaturated polymerizable monomers is at least 5 mol % and up to and including 30 mol %, and typically at least 8 mol % and up to and including 20 mol %. The amount of recurring units derived from one or more of the b) group of ethylenically unsaturated polymerizable monomers is at least 40 mol % and up to and including 80 mol %, and typically at least 55 mol % and up to and including 70 mol %. The amount of recurring units derived from one or more of the c) group of ethylenically unsaturated polymerizable monomers, can be 0 mol % and when present, is up to and including 30 mol %, and typically at least 5 mol % and up to and including 15 mol %. The amount of recurring units derived from one or more of the d) group of ethylenically unsaturated polymerizable monomers can be 0 mol % and when present, is up to and including 30 mol %, and typically at least 2 mol % and up to and including 10 mol %. Moreover, the amount of recurring units derived from one or more of the e) group of ethylenically unsaturated polymerizable monomers is at least 5 mol % and up to and including 40 mol %, and typically at least 8 mol % and up to and including 20 mol %. All of these amounts are based on the total moles of recurring units in the specific first polymeric binder.

In some embodiments, each of the one or more first polymeric binders has an acid number of at least 65 meq KOH/g of polymer and up to and including 130 meq KOH/g of polymer, and at least one of the first polymeric binders comprises recurring units derived from at least:

an N-alkoxymethyl (meth)acrylamide or alkoxymethyl (alkyl)acrylate, or

an ethylenically unsaturated polymerizable monomer having pendant 1H-tetrazole groups.

In still other embodiments, at least one of the first polymeric binders comprises recurring units derived from both:

an N-alkoxymethyl (meth)acrylamide or alkoxymethyl (alkyl)acrylate, and

an ethylenically unsaturated polymerizable monomer having pendant 1H-tetrazole groups.

For example, in some embodiments of the precursor of this invention, at least one of the first polymeric binders comprises at least 5 weight % and up to and including 30 weight % of recurring derived from one or more N-alkoxymethyl (meth)acrylamides, based on the total polymer recurring units.

Each of the one or more first polymeric binders has a solubility of less than 100 mg/g when agitated for 24 hours at 25° C. in either an 80 weight % aqueous solution of 2-butoxyethanol or an 80 weight % aqueous solution of diacetone alcohol.

These first polymeric binders can be prepared using known synthetic emulsion polymerization procedures and readily available or prepared ethylenically unsaturated polymerizable monomers, polymerization initiators, and emulsifying surfactants.

The inner imageable layer can also include one or more polymeric binders that are different in composition than the first polymeric binders defined above. They are also different than the second polymeric binders described below for the ink-receptive outer imageable layer. Such “secondary” polymeric binders can be present in the inner imageable layer in an amount of at least 3 weight % and up to and including 30 weight %. Such secondary polymeric binders can include but are not limited to, oligomers, polyurethanes, acrylic copolymers, poly(vinyl acetal)s, phenolic binders such as novolaks and resoles, cellulose esters, maleic anhydride copolymers, and maleimide copolymers.

In most embodiments, the inner imageable layer further comprises an infrared radiation absorber that absorbs radiation of at least 700 and up to and including 1400 and typically of at least 700 and up to and including 1200 nm. In most embodiments, the infrared radiation absorber is present only in the inner imageable layer. The infrared radiation absorber can be present in the multi-layer lithographic printing plate precursor in an amount of generally at least 0.5% and up to and including 30% and typically at least 3 weight % and up to and including 25 weight %, based on the total dry weight of the layer in which the compound is located. The particular amount of a given compound to be used could be readily determined by one skilled in the art.

Useful infrared radiation absorbers include but are not limited to, azo dyes, squarilium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. Nos. 5,208,135 (Patel et al.), 6,153,356 (Urano et al.), 6,264,920 (Achilefu et al.), 6,309,792 (Hauck et al.), 6,569,603 (noted above), 6,787,281 (Tao et al.), 7,135,271 (Kawaushi et al.), and EP 1,182,033A2 (noted above) all of which are incorporated herein by reference. Infrared radiation absorbing N-alkylsulfate cyanine dyes are described for example in U.S. Pat. No. 7,018,775 (Tao) that is incorporated herein by reference. A general description of one class of suitable cyanine dyes is shown by the formula in paragraph [0026] of WO 2004/101280 (Munnelly et al.) that is incorporated herein by reference.

In addition to low molecular weight IR-absorbing dyes having IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (Hauck et al.), 6,264,920 (Achilefu et al.), 6,153,356 (Urano et al.), and 5,496,903 (Watanabe et al.) all of which are incorporated herein by reference. Suitable dyes can be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer) that is incorporated herein by reference.

The dry coating weight of the inner imageable layer is at least 0.5 g/m² and up to and including 2.5 g/m².

### Ink-Receptive Outer Imageable Layer

The ink-receptive outer imageable layer is disposed over the inner layer and in most embodiments there are no intermediate layers between the inner imageable layer and the ink-receptive outer imageable layer.

The ink-receptive outer imageable layer comprises one or more second polymeric binders that are different in chemical composition than the one or more first polymeric binders described above for the inner imageable layer. Useful second polymeric binders include but are not limited to, poly(vinyl phenols) or derivatives thereof. Such polymers can also include pendant acidic groups such as carboxylic (carboxy), sulfonic (sulfo), phosphonic (phosphono), or phosphoric acid groups that are incorporated into the polymer molecule backbone or pendant (side chains) to the polymer backbone. Other useful additional phenolic polymers include but are not limited to, novolak resins, resole resins, poly(vinyl acetals) having pendant phenolic groups, and mixtures of any of these resins (such as mixtures of one or more novolak resins and one or more resole resins). Generally, such resins have a number average molecular weight of at least 3,000 and up to and including 200,000, and typically at least 6,000 and up to and including 100,000, as determined using conventional procedures such as gel permeation chromatography (GPC). Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or an m,p-cresol mixture with formaldehyde using conventional conditions. For example, some useful novolak resins include but are not limited to, xylenol-cresol resins, for example, SPN400, SPN420, SPN460, and VPN1100 (that are available from AZ Electronics) and EP25D40G and EP25D50G (noted below for the Examples) that have higher molecular weights, such as at least 4,000.

Other useful second polymeric binders include polyvinyl compounds having phenolic hydroxyl groups, include poly(hydroxystyrenes) and copolymers containing recurring units of a hydroxystyrene and polymers and copolymers containing recurring units of substituted hydroxystyrenes. Also useful are branched poly(hydroxystyrenes) having multiple branched hydroxystyrene recurring units derived from 4-hydroxystyrene as described for example in U.S. Pat. Nos. 5,554,719 (Sounik) and 6,551,738 (Ohsawa et al.), and U.S. Published Patent Applications 2003/0050191 (Bhatt et al.), 2005/0051053 (Wisnudel et al.), and 2008/2008/0008956 (Levanon et al.) that are incorporated herein by reference. For example, such branched hydroxystyrene polymers comprise recurring units derived from a hydroxystyrene, such as from 4-hydroxystyrene, which recurring units are further substituted with repeating hydroxystyrene units (such as 4-hydroxystyrene units) positioned ortho to the hydroxy group. These branched polymers can have a weight average molecular weight (M_{W}) of at least 1,000 and up to and including 30,000. In addition, they can have a polydispersity of less than 2. The branched poly(hydroxystyrenes) can be homopolymers or copolymers with non-branched hydroxystyrene recurring units.

Another group of useful second polymeric binders are poly(vinyl phenol) and derivatives thereof that are obtained generally by polymerization of vinyl phenol monomers, that is, substituted or unsubstituted vinyl phenols. Some vinyl phenol copolymers are described in EP 1,669,803A (Barclay et al.) that is incorporated herein by reference.

Still other useful second polymeric binders in the ink-receptive outer imageable layer are selected from the group consisting of at least one acidic polyurethane, at least one carboxy-functionalized phenolic resin (such as a carboxy-functionalized novolak or resole), and a combination of at least one acidic polyurethane and at least one carboxy-functionalized phenolic resin (as noted above). For example, the phenolic groups in novolaks and resoles can be etherified with chloro acetic acid to provide functional carboxyl groups. More details of such functionalized resins are provided for example, in U.S. Pat. No. 7,582,407 (Savariar-Hauck et al.) that is incorporated herein by reference, and this patent describes some useful functionalized novolaks and resoles. The functional acidic groups can be pendant from the resin backbone, or they can be incorporated as part of the resin backbone. Particularly useful functionalized resins are carboxy-functionalized novolaks and carboxy-functionalized resoles.

Other useful second polymeric binders include poly(vinyl acetal)s as described in U.S. Pat. Nos. 7,163,777 (Ray et al.), 7,260,653 (Huang et al.), 7,241,556 (Saraiya et al.), and 7,781,148 (Savariar-Hauck et al.) and U.S. Patent Application Publications 2007/0065737 (Kitson et al.) and 2009/0186301 (Ray et al.), all of which are incorporated herein by reference.

In many embodiments, the ink-receptive outer imageable layer is substantially free of infrared radiation absorbers, meaning that none of these compounds are purposely incorporated therein and insubstantial amounts diffuse into it from other layers. However, in other embodiments, an infrared radiation absorber can be in both the ink-receptive outer imageable layer and the inner imageable layer, as described for example in EP 1,439,058A2 (Watanabe et al.) and EP 1,738,901A1 (Lingier et al.), or the infrared radiation absorber can be located in an intermediate layer between the two imageable layers, or the infrared radiation absorber can be any or all of the three noted layers.

The ink-receptive outer imageable layer can also include colorants as described for example in U.S. Pat. No. 6,294,311 (Shimazu et al.) including triarylmethane dyes such as ethyl violet, crystal violet, malachite green, brilliant green, Victoria blue B, Victoria blue R, and Victoria pure blue BO. These compounds can act as contrast dyes that distinguish the non-exposed regions from the exposed regions in the developed imageable element. The ink-receptive outer imageable layer can optionally include contrast dyes, printout dyes, coating surfactants, dispersing aids, humectants, biocides, viscosity builders, drying agents, defoamers, preservatives, and antioxidants.

Other materials can be present in the ink-receptive outer imageable layer including but not limited to, coating surfactants, dispersing aids, humectants, biocides, viscosity builders, drying agents, defoamers, preservatives, and antioxidants. Such materials can be incorporated in amounts that would be readily apparent to a skilled worker in the art. For example, the following publications describe optional components for the ink-receptive outer imageable layer useful in positive-working lithographic printing plate precursors: EP 1,543,046 (Timpe et al.), WO 2004/081662 (Memetea et al.), U.S. Pat. Nos. 6,255,033 (Levanon et al.), 6,280,899 (Hoare et al.), 6,391,524 (Yates et al.), 6,485,890 (Hoare et al.), 6,558,869 (Hearson et al.), 6,706,466 (Parsons et al.), 6,541,181 (Levanon et al.), 7,223,506 (Kitson et al.), 7,247,418 (Saraiya et al.), 7,270,930 (Hauck et al.), 7,279,263 (Goodin), and 7,399,576 (Levanon), EP 1,627,732 (Hatanaka et al.), and U.S. Published Patent Applications 2005/0214677 (Nagashima), 2004/0013965 (Memetea et al.), 2005/0003296 (Memetea et al.), and 2005/0214678 (Nagashima) all of which are incorporated herein by reference.

The ink-receptive outer imageable layer can further comprise one or more developability-enhancing compounds. A “developability-enhancing compound” is an organic compound that, when added to the ink-receptive outer imageable layer, reduces the minimum exposure energy required to completely remove this layer in the exposed regions, in a suitable developer selected for the ink-receptive outer imageable layer, relative to the minimum exposure energy required to completely remove the same ink-receptive outer imageable layer in the exposed regions except for the exclusion of the organic compound. This difference will depend up on the particular organic compound and imageable layer composition used. In addition, such organic compounds can also be characterized as not substantially absorbing exposing infrared radiation selected for the particular ink-receptive outer imageable layer, and generally have a molecular weight of less than 1000 g/mol.

Acidic Developability-Enhancing Compounds (ADEC), such as carboxylic acids or cyclic acid anhydrides, sulfonic acids, sulfinic acids, alkylsulfuric acids, phosphonic acids, phosphinic acids, phosphonic acid esters, phenols, sulfonamides, or sulfonimides can be present in the ink-receptive outer imageable layer. Representative examples of such compounds are provided in to [0036] of U.S. Patent Application Publication 2005/0214677 (Levanon et al.) that is incorporated herein by reference.

The ink-receptive outer imageable layer can also include a developability-enhancing composition containing one or more developability-enhancing compounds (DEC) as described in U.S. Patent Publication No. 2009/0162783 that is also incorporated herein by reference. Still other useful developability-enhancing compounds are also described in this publication using the following Structure (DEC₁):

[HO—C(═O)]ₘ—B-A-[N(R₄)(R₅)]ₙ (DEC₁)

wherein R₄ and R₅ in Structure DEC₁ are independently hydrogen or substituted or unsubstituted alkyl groups, substituted or unsubstituted cycloalkyl groups, or substituted or unsubstituted aryl groups, A is an organic linking group that comprises a substituted or unsubstituted phenylene directly attached to —[N(R₄)(R₅)]ₙ, B is a single bond or an organic linking group having at least one carbon, oxygen, sulfur, or nitrogen atom in the chain, m is an integer of 1 or 2, n is an integer of 1 or 2. The “B” organic linking group can be defined the same as A is defined above except that it is not required that B contain an arylene group, and usually B, if present, is different than A.

The one or more developability-enhancing compounds described above can be present in the ink-receptive outer imageable layer in an amount of at least 1 weight % and up to and including 30 weight %, or typically at least 2 eight % and up to and including 20 weight %.

The lithographic printing plate precursors can be prepared by sequentially applying an inner imageable layer formulation over the surface of a substrate, and then applying an ink-receptive outer imageable layer formulation over the inner imageable layer using conventional coating or lamination methods. It is important to avoid intermixing of the two formulations for example, by using different coating solvents in the formulations.

The inner imageable layer and ink-receptive outer imageable layers can be formed by dispersing or dissolving the desired ingredients in a suitable coating solvent(s), and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying techniques.

The selection of solvents used to coat both formulations depends upon the nature of the first and second polymeric binders, other polymeric materials, and other components in the formulations. To prevent the inner imageable layer and the ink-receptive outer imageable layer formulations from mixing or the inner imageable layer from dissolving when the ink-receptive outer imageable layer formulation is applied, the ink-receptive outer imageable layer formulation should be coated from a solvent in which the first polymeric binder(s) of the inner imageable layer are insoluble.

Generally, the inner imageable layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane.

The ink-receptive outer imageable layer formulation can be coated out of solvents or solvent mixtures that do not dissolve the inner imageable layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof.

The dry coating weight for the ink-receptive outer imageable layer can be at least 0.5 g/m² and up to and including 3.5 g/m² and typically at least 1 g/m² and up to and including 2.5 g/m².

After drying the layers, the resulting lithographic printing plate precursors can be further “conditioned” with a heat treatment for at least 40° C. and up to and including 90° C. for at least 4 hours (for example, at least 20 hours) under conditions that inhibit the removal of moisture from the dried layers. For example, the heat treatment is carried out for at least 50° C. and up to and including 70° C. for at least 24 hours. During the heat treatment, the lithographic printing plate precursors are wrapped or encased in a water-impermeable sheet material to represent an effective barrier to moisture removal from the precursors, or the heat treatment of the precursors is carried out in an environment in which relative humidity is controlled to at least 25%. In addition, the water-impermeable sheet material can be sealed around the edges of the precursors, with the water-impermeable sheet material being a polymeric film or metal foil that is sealed around the edges of the precursors.

In some embodiments, this heat treatment can be carried out with a stack comprising at least 100 of the same lithographic printing plate precursors, or when the precursor is in the form of a coil or web. When conditioned in a stack, the individual precursors can be separated by suitable interleaving papers. The interleaving papers can be kept between the imageable elements after conditioning during packing, shipping, and use by the customer. In some embodiments, no heat treatment is needed.

### Imaging Conditions

During use, the lithographic printing plate precursor is exposed to a suitable source of exposing radiation depending upon the infrared radiation absorber present in the precursor to provide specific sensitivity that is at a wavelength of at least 700 nm and up to and including 1400 nm. In some embodiments, imagewise exposure is carried out using radiation the range of at least 700 nm and up to and including 1250 nm.

For example, imaging can be carried out using imaging or exposing radiation from an infrared radiation-generating laser (or array of such lasers). Imaging also can be carried out using imaging radiation at multiple wavelengths at the same time if desired. The laser used to expose the lithographic printing plate precursor is usually a diode laser, because of the reliability and low maintenance of diode laser systems, but other lasers such as gas or solid-state lasers can also be used. The combination of power, intensity and exposure time for laser imaging would be readily apparent to one skilled in the art and a number of useful laser imaging apparatus are available in the industry.

The imaging apparatus can be configured as a flatbed recorder or as a drum recorder, with the lithographic printing plate precursor mounted to the interior or exterior cylindrical surface of the drum. An example of an useful imaging apparatus is available as models of Kodak® Trendsetter platesetters available from Eastman Kodak Company that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen USA, Chicago, Ill.) that operates at a wavelength of 810 nm.

Imaging with infrared radiation can be carried out generally at imaging energies of at least 30 mJ/cm² and up to and including 1000 mJ/cm², and typically at least 50 mJ/cm² and up to and including 500 mJ/cm² depending upon the sensitivity of the imageable layers in the precursor. With these platesetters, any imaging parameters such as the “surface depth” parameter of a Magnus 800 platesetter (Eastman Kodak Company) or the “focus” parameter of a PlateRite 4300 platesetter (Dainippon Screen Company), are decided by observing the difference in contrast between exposed regions and non-exposed regions in a stepwise imaging process. By using such as stepwise imaged lithographic printing plate precursor, a shortened printing run is possible and the obtained prints are also useful for determining such imaging parameters.

While laser imaging is desired in the practice of this invention, thermal imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

### Development and Printing

After imaging, the imaged lithographic printing plate precursors can be processed “off-press” using a suitable processing solution described herein, for example water or an alkaline processing solution. When the positive-working lithographic printing plate precursors are imaged and processed, the imaged (exposed) regions of both imageable layers and any intermediate layers are removed during processing while the non-exposed regions remain, revealing the hydrophilic substrate under the exposed regions.

Development off-press can be accomplished using what is known as “manual” development, “dip” development, or processing with an automatic development apparatus (processor). In the case of “manual” development, development is conducted by rubbing the entire imaged precursor with a sponge or cotton pad sufficiently impregnated with a suitable processing solution (described below), and followed by rinsing with water. “Dip” development involves dipping the imaged precursor in a tank or tray containing the appropriate processing solution for at least 10 seconds and up to and including 60 seconds (especially at least 20 seconds and up to and including 40 seconds) under agitation, followed by rinsing with water with or without rubbing with a sponge or cotton pad. The use of automatic development apparatus is well known and generally includes pumping a developer or processing solution into a developing tank or ejecting it from spray nozzles. The imaged precursor is contacted with the developer in an appropriate manner. The apparatus can also include a suitable rubbing mechanism (for example a brush or roller) and a suitable number of conveyance rollers. Some developing apparatus include laser exposure means and the apparatus is divided into an imaging section and a developing section.

Both aqueous alkaline developers and organic solvent-containing developers or processing solutions can be used. Some useful developer solutions are described for example, in U.S. Pat. Nos. 7,507,526 (Miller et al.) and 7,316,894 (Miller et al.). Developer solutions commonly include surfactants, chelating agents (such as salts of ethylenediaminetetraacetic acid), organic solvents (such as benzyl alcohol), and alkaline components (such as inorganic metasilicates, organic metasilicates, hydroxides, and bicarbonates).

Useful alkaline aqueous developer solutions include 3000 Developer, 9000 Developer, GOLDSTAR Developer, GREENSTAR Developer, ThermalPro Developer, PROTHERM Developer, MX1813 Developer, and MX1710 Developer (all available from Eastman Kodak Company). These compositions also generally include surfactants, chelating agents (such as salts of ethylenediaminetetraacetic acid), and alkaline components (such as inorganic metasilicates, organic metasilicates, hydroxides, and bicarbonates).

Organic solvent-containing developers are generally single-phase processing solutions of one or more organic solvents that are miscible with water. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol. The organic solvent(s) is generally present in an amount of at least 0.5 weight % and up to 15 weight % based on total developer weight. The organic solvent-containing developers can be neutral, alkaline, or slightly acidic in pH (for example, a pH of 5), and typically, they are alkaline in pH. Representative organic solvent-containing developers include ND-1 Developer, Developer 980, Developer 1080, 2 in 1 Developer, 955 Developer, D29 Developer (described below), and 956 Developer (all available from Eastman Kodak Company).

The processing solution (developer) can have a pH of at least 3 and up to and including 13.5, or typically at least 7 and up to and including 13.5.

In some useful embodiments of the method of this invention, the processing solution used for development has a pH of 12.5 or less, and a pH that can be as low as 6. Typically, the pH is at least 7 and up to and including 13.5 or at least 7.5 and up to and including 12. This low pH processing solution can include at least 0.001 weight % and up to and including 1 weight % of a water-soluble or water-dispersible, non-1R-sensitive compound that has a heterocyclic moiety with a quaternary nitrogen in the 1-position of the heterocyclic ring. This compound also has one or more electron donating substituents attached to the heterocyclic ring, at least one of which electron donating substituents is attached in the 2-position. The amount of these compounds can be at least 0.1 weight % and up to and including 0.8 weight %. These compounds are sometimes identified herein as “additives” for the processing solution.

More specifically, the water-soluble or water-dispersible compounds have a dialkylaminophenyl or 3-indolyl group in the 2-position of the heterocyclic ring. Examples of such compounds include but are not limited to, Thioflavine T, Astrazon Orange G, and Basic Violet 16.

Thus, after exposure to infrared radiation, the exposed regions of the inner imageable layer and the ink-receptive outer imageable layer are more removable in the processing solution having a pH of 12.5 or less than before exposure to the infrared radiation.

In addition, a processing solution useful in this invention can further comprise at least 0.01 weight % of any one or more of the following: anionic or nonionic surfactants, alkanolamines, organic solvents, organic phosphonic acids or polycarboxylic acids or salts thereof that are different from the anionic surfactant, and hydrophilic film-forming polymers that provide protective coatings on the imaged and processed surface of the lithographic printing plate. For example, at least 0.01 weight % and up to and including 15 weight % of one or more hydrophilic film-forming polymers can be present in the processing solution.

In addition, the processing solution can also comprise up to and including 8 weight % (based on total processing solution weight) of one or more organic solvents (described below). Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol.

The processing solutions are preferably free of silicates and metasilicates, and hydroxides, meaning that none of these compounds is intentionally added to the processing solution and the processing solutions include less than 2 weight % of such compounds.

In some embodiments, the processing solution has a pH at least 8.5 and up to and including 11.5, and comprises at least 0.1 weight % and up to and including 0.8 weight % of one or more of Thioflavine T, Astrazon Orange G, and Basic Violet 16, and the processing solution is essentially free of silicates and metasilicates, and further comprises at least 0.1 weight % and up to and including 5 weight % of an alkanolamine, organic phosphonic acid, or polycarboxylic acid or salt thereof that is different from an anionic surfactant, or hydrophilic film-forming polymer to form a protective coating, or mixtures thereof.

The processing solution can further include one or more surfactants that can act as “coating-attack suppressing agents” that are developer-soluble compounds that suppress developer attack of the outer layer in addition to the additives used according to this invention. “Developer-soluble” means that enough of the agent(s) will dissolve in the processing solution to suppress attack by the processing solution. Typically, the coating-attack suppressing agents are developer-soluble polyethoxylated, polypropoxylated, or polybutoxylated compounds that include recurring —(CH₂—CHRₐ—O—)— units in which Rₐ is hydrogen or a methyl or ethyl group. Representative compounds of this type include but are not limited to, polyglycols and polycondensation products having the noted recurring units. Examples of such compounds and representative sources, tradenames, or methods of preparing are described for example in U.S. Pat. No. 6,649,324 (Fiebag et al.).

Other useful processing solutions of this invention can be prepared by mixing an “additive” as described above in silicate-free carbonate processing solutions as described for example in U.S. Patent Application Publication 2009-0197052 (Levanon et al.) that is incorporated herein by reference. Similarly, the “additive” can be mixed with carbonate processing solutions containing organic solvents, organic amines, anionic surfactants, or combinations thereof, as described for example in U.S. Patent Application Publications 2009-0291387 (Levanon et al.) and 2010-0047723 (Levanon et al.), both of which are incorporated herein by reference. Useful organic amines include those whose conjugated acids have a pKa greater than 9 and a boiling point greater than 150° C. Such organic amines may be present in an amount of at least 0.03 N or at least 0.03 N and up to and including 1.5 N, and include ethanol amine, 4-aminopyridine, 1,5-diaminopentane, 4-(2-aminoethyl)phenol, 1-ephedrine, 2-(ethylamino)ethanol, 3-amino-1-propanol, and 2-(2-aminoethylamino)ethanol. Further details are provided in the noted US '723 publication.

In some embodiments, the processing solution consists essentially of a carbonate, organic solvent, and the water-soluble or water-dispersible, non-IR-sensitive compound that has a heterocyclic moiety with a quaternary nitrogen in the 1-position of the heterocyclic ring. Thus, such solutions contain no other compounds that have a meaningful effect on development.

The processing solution (or developer) can be applied to the imaged precursor by rubbing, spraying, jetting, dipping, immersing, slot die coating (for example see FIGS. 1 and 2 of U.S. Pat. No. 6,478,483 of Maruyama et al.) or reverse roll coating (as described in FIG. 4 of U.S. Pat. No. 5,887,214 of Kurui et al.), or by wiping the outer layer with the processing solution or contacting it with a roller, impregnated pad, or applicator. For example, the imaged precursor can be brushed with the processing solution, or it can be poured onto or applied by spraying the imaged surface with sufficient force to remove the non-exposed regions using a spray nozzle system as described for example in [0124] of EP 1,788,431A2 (noted above) and U.S. Pat. No. 6,992,688 (Shimazu et al.). As noted above, the imaged precursor can be immersed in the processing solution and rubbed by hand or with an apparatus. To assist in the removal of the backside coating, a brush roller or other mechanical component can be placed in contact with the backside coating during processing. Alternatively, the processing solution can be sprayed using a spray bar using a sufficient force.

The processing solution can also be applied in a processing unit (or station) in a suitable apparatus that has at least one roller for rubbing or brushing the imaged precursor while the processing solution is applied. Residual processing solution can be removed (for example, using a squeegee or nip rollers) or left on the resulting lithographic printing plate without any rinsing step. Excess processing solution can be collected in a tank and used several times, and replenished if necessary from a reservoir. The processing solution replenisher can be of the same concentration as that used in processing, or be provided in concentrated form and diluted with water at an appropriate time.

In most embodiments, there are no intermediate treatments of the lithographic printing plate precursor between imagewise exposing and the processing procedure.

Following off-press development, the resulting lithographic printing plate can be postbaked or quickbaked as described in EP 1,588,220 (Machuel et al.), with or without blanket or floodwise exposure to UV or visible radiation. Alternatively, a blanket (uniformly) UV or visible radiation exposure can be carried out, without a postbake operation. For example, the imaged and processing lithographic printing plate can be baked at a temperature above room temperature (greater than 25° C.) for at least 1 minute or uniformly exposed to infrared radiation.

Printing can be carried out by putting the imaged and developed lithographic printing plate on a suitable printing press. The lithographic printing plate is generally secured in the printing plate using suitable clamps or other holding devices. Once the lithographic printing plate is secured in the printing press, printing is carried out by applying a lithographic printing ink and fountain solution to the printing surface of the lithographic printing plate. The fountain solution is taken up by the surface of the hydrophilic substrate revealed by the imaging and processing steps, and the ink is taken up by the remaining non-exposed regions of the ink-receptive outer imageable layer. The ink is then transferred to a suitable receiving material (such as cloth, paper, metal, glass, or plastic) to provide a desired impression of the image thereon. If desired, an intermediate “blanket” roller can be used to transfer the ink from the lithographic printing plate to the receiving material (for example, sheets of paper). The lithographic printing plates can be cleaned between impressions, if desired, using conventional cleaning means.

The present invention provides at least the following embodiments and combinations thereof, but other combinations of features are considered to be within the present invention as a skilled artisan would appreciate from the teaching of this disclosure:

1. A positive-working lithographic printing plate precursor comprising a substrate having a hydrophilic surface, and two or more layers disposed on the substrate, at least one of the layers comprising an infrared radiation absorber,

the two or more layers comprising:

an inner imageable layer disposed over the substrate, which inner imageable layer comprises one or more first polymeric binders that are present in a total amount of at least 50 weight % and up to and including 97 weight %, based on total inner imageable layer dry weight, and

an ink-receptive outer imageable layer disposed over the inner imageable layer, which ink-receptive outer imageable layer comprises one or more second polymeric binders that are different than the first polymeric binder,

wherein each of the one or more first polymeric binders has a weight average molecular weight of at least 200,000

2. The precursor of embodiment 1, wherein each of the one or more first polymeric binders has a polydispersity of at least 4.

3. The precursor of embodiment 1 or 2, wherein each of the one or more first polymeric binders has a weight average molecular weight of at least 200,000 and up to and including 600,000, and a polydispersity of at least 4 and up to and including 10.5.

4. The precursor of any of embodiments 1 to 3, wherein each of one or more first polymeric binders has an acid number of at least 40 meq KOH/g of polymer, and at least one of the first polymeric binders comprises recurring units randomly distributed along the polymer chain, that are derived from one or more of the following groups of ethylenically unsaturated polymerizable monomers:

a) N-alkoxymethyl (meth)acrylamides or alkoxymethyl (alkyl)acrylates,

b) ethylenically unsaturated polymerizable monomers having pendant cyano groups,

c) ethylenically unsaturated polymerizable monomers having pendant 1H-tetrazole groups,

d) ethylenically unsaturated polymerizable monomers having one or more carboxy, sulfo, or phospho groups, and

e) ethylenically unsaturated polymerizable monomers represented by Structures (D1) through (D4):

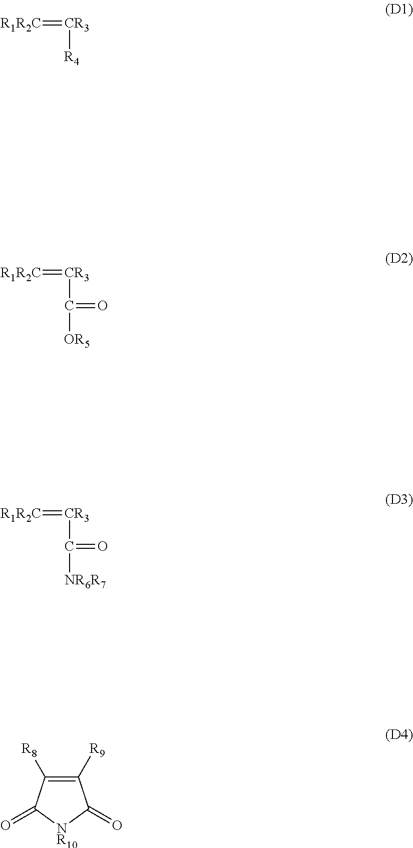

wherein R₁ and R₂ are independently hydrogen or alkyl, alkenyl, phenyl, halo, alkoxy, or acyloxy groups, or R₁ and R₂ together can form a cyclic ring with the carbon atom to which they are attached,

R₃ and R₄ are independently hydrogen or alkyl, phenyl, or halo groups,

R₅ is an alkyl, alkenyl, cycloalkyl, or phenyl group,

R₆ through R₉ are independently hydrogen or alkyl, alkenyl, phenyl, halo, alkoxy, acyl, or acyloxy groups, and

R₁₀ is hydrogen or an alkyl, phenyl, or hydroxy group.

5. The precursor of any of embodiments 1 to 4, wherein each of the one or more first polymeric binders has an acid number of from 65 meq KOH/g of polymer and up to and including 130 meq KOH/g of polymer, and at least one of the first polymeric binders comprises recurring units derived from at least:

a) an N-alkoxymethyl (meth)acrylamide or alkoxymethyl (alkyl)acrylate, and

c) an ethylenically unsaturated polymerizable monomer having pendant 1H-tetrazole groups.

6. The precursor of any of embodiments 1 to 4, wherein at least one first polymeric binders comprises recurring units derived from both:

a) an N-alkoxymethyl (meth)acrylamide or alkoxymethyl (alkyl)acrylate, and

c) an ethylenically unsaturated polymerizable monomer having pendant 1H-tetrazole groups.

7. The precursor of any of embodiments 1 to 6, wherein at least one of the first polymeric binders comprises at least 5 weight % and up to and including 30 weight % of recurring derived from one or more N-alkoxymethyl (meth)acrylamides, based on the total polymer recurring units.

8. The precursor of any of embodiments 1 to 7, wherein the ink-receptive outer imageable layer comprises a second polymeric binder selected from the group consisting of: at least one acidic polyurethane, at least one carboxy-functionalized phenolic resin, and a combination of at least one acidic polyurethane and at least one carboxy-functionalized phenolic resin.

9. The precursor of any of embodiments 1 to 8, wherein the infrared radiation absorber is present in an amount of at least 0.5 weight % and up to and including 30 weight %.

10. The precursor of any of embodiments 1 to 9, wherein the infrared radiation absorber is present only in the inner imageable layer.

11. The precursor of any of embodiments 1 to 10, when the inner imageable layer and the ink-receptive outer imageable layer are exposed to infrared radiation, they become more removable in a developer having a pH of 12.5 or less than before exposure to infrared radiation.

12. The precursor of any of embodiments 1 to 11, wherein each of the one or more first polymeric binders has a solubility of less than 100 mg/g when agitated for 24 hours at 25° C. in either an 80 weight % aqueous solution of 2-butoxyethanol or an 80 weight % aqueous solution of diacetone alcohol.

13. The precursor of any of embodiments 1 to 12, wherein the substrate is an aluminum-containing substrate.

14. A method for making a lithographic printing plate, comprising:

imagewise exposing the positive-working lithographic printing plate precursor of any of embodiments 1 to 13 to infrared radiation, thereby forming an imaged precursor having exposed and non-exposed regions in the inner imageable layer and the ink-receptive outer imageable layer, and

processing the imaged precursor to remove the exposed regions of the inner imageable layer and the ink-receptive outer imageable layer and to form a lithographic printing plate.

15. The method of embodiment 14, wherein there are no intermediate treatment of the precursor between the imagewise exposing and the processing.

16. The method of embodiment 14 or 15, wherein the processing is carried out using a processing solution having a pH of at least 6 and up to and including 12.5.

17. The method of embodiment 14 or 15, wherein the processing is carried out using a processing solution having a pH of at least 7 and up to and including 13.5.

18. The method of any of embodiments 14 to 17, wherein after the imagewise exposing and processing, the lithographic printing plate is baked at a temperature above room temperature for at least 1 minute, or the lithographic printing plate is uniformly exposed to infrared radiation.

19. A lithographic printing plate prepared from any of embodiments 14 to 18.

The following Examples are provided to illustrate the practice of this invention and are not meant to be limiting in any manner.

The following materials were used in the following Examples:

Ethyl violet is assigned C.I. 42600 (CAS 2390-59-2, λmax=596 nm) and has a formula ofp-(CH3CH2)2NC6H4)3C⁺Cl

DEK represents diethyl ketone.

IR Dye KAN 165493 is represented by the following formula and can be obtained from Eastman Kodak Company (Rochester, N.Y.):

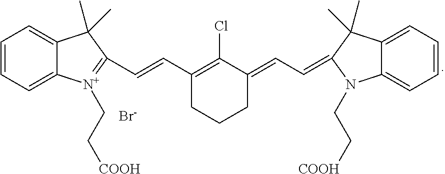 [SMILES: CC1(C)C(/C=C/C2=C(Cl)C(=C/C=C3/N(CCC(=O)O)c4ccccc4C3(C)C)/CCC2)=[N+](CCC(=O)O)c2ccccc21 ; [Br-]]

PMA represents 1-methoxy-2-propyl acetate.

BLO is γ-butyrolactone.

Byk® 307 a polyethoxylated dimethylpolysiloxane copolymer that is available from Byk Chemie (Wallingford, Conn.).

D11 is ethanaminium, N-[4-[[4-(diethylamino)phenyl][4-(ethylamino)-1-naphthalenyl]methylene]-2,5-cyclohexadien-1-ylidene]-N-ethyl-, salt with 5-benzoyl-4-hydroxy-2-methoxybenzenesulfonic acid (1:1) as supplied by PCAS (Longjumeau, France), having the following structure:

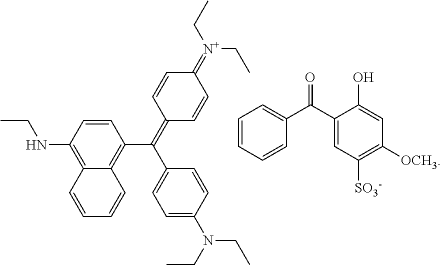

Co1030 is a nanoparticle dispersion from Evoniks (Germany).

Polymer A was an acidic novolak based on SPN562 (phenolic groups etherified with chloro acetic acid); theoretical AN=70, Mw=5600. SPN562 is a 44 weight % solution of m-cresol novolak from AZ Chemicals (Germany).

Substrate A was a 0.3 mm gauge aluminum sheet that had been electrochemically grained, anodized, and subjected to treatment with poly(vinyl phosphonic acid).

Solvent Mixture A was a mixture of MEK:PMA:BLO:H₂O:Dioxalane, 45/20/10/10/15 weight ratio.

Solvent Mixture B was a mixture of MEK, Dowanol® PMA, and Dowanol® PM at 45:10:45 weight ratio.

Developer A is a low pH (pH=10.3) developer made by mixing parts by weight, 790 g of water, 23 g of diethanolamine, 50 g of Ethylan™ HB4, 335 g of Lugalvan® BNO 12, 50 g of Amphotensid B5, 48 g of Pluronic® PE 6400, 5.1 g of phosphoric acid (85 weight %), and 0.4 g of Astrazon® Orange G.

Polyurethane Resin was composed of dimethylolpropinic acid/bis[4-(2-hydroxyethoxy)phenyl]sulfone/1,6-hexanediol/Polyfox® PF 6320 (from Omnova)/4,4′-diphenylmethane diisocyanate that was prepared using known conditions.

SWORD Ultra is a commercially available positive-working, multi-layer lithographic printing plate precursor (Eastman Kodak Company).

Synthesis of Resins:

To synthesize the Resins shown in TABLE I, the following general procedure was followed.

A pre-mixture of monomers, initiator, and solvents was made and flushed with nitrogen. One-fourth of the pre-mixture was added to a 500 ml 4-neck round bottomed flask fitted with stirring, temperature monitoring, reflux, and then heated to 80° C. while purging with nitrogen. The remainder of the pre-mixture was added slowly over three hours. After a total reaction time of 6.5 hours, the resulting reaction mixture was cooled down and the resulting polymer precipitated in water, filtered, and washed with water. The resulting polymer was dried at 40° C. for 2 days. “Monomer feed concentration” was calculated as the total monomer weight (grams) divided by the total weight of monomers, solvents, and initiator (grams), expressed as a percentage.

TABLE I

| Component | Resin 1A | Resin 1B | Resin 2A | Resin 2B | Resin 4 | Resin 5 | Resin 6A | Resin 6B |
|---|---|---|---|---|---|---|---|---|
| DMSO (g) | 0 | 0 | 290 | 190 | 166 | 105 | 0 | 0 |
| DMAC (g) | 200 | 193 | 0 | 0 | 0 | 0 | 133 | 88 |
| Monomer Feed | 25% | 40% | 40% | 30% | 30% | 40% | 40% | 30% |
| Concentration (%) | | | | | | | | |
| Methacrylamide- | 11.78 | 23.56 | 23.56 | 23.56 | 15.3 | 15.3 | 0 | 0 |
| N-tetrazole (g) | | | | | | | | |
| N-Phenyl | 13.32 | 26.64 | 26.64 | 26.64 | 23.98 | 23.98 | 13.32 | 13.32 |
| maleimide (g) | | | | | | | | |
| Methacrylic acid | 2.65 | 5.3 | 6.89 | 6.89 | 2.65 | 2.65 | 9.27 | 9.27 |
| (g) | | | | | | | | |
| Methacrylamide | 0 | 0 | 0 | 0 | 6.55 | 6.55 | 0 | 0 |
| (g) | | | | | | | | |
| Acrylonitrile (g) | 29.64 | 53.88 | 54.9 | 54.9 | 22.45 | 22.45 | 26.94 | 26.94 |
| N-Methoxymethyl | 8.85 | 17.71 | 13.28 | 13.28 | 0 | 0 | 8.8 | 8.8 |
| methacrylamide | | | | | | | | |
| (g) | | | | | | | | |
| AIBN (g) | 1.65 | 1.4 | 1.35 | 1.35 | 0.74 | 0.74 | 0.6 | 0.6 |
| Yield | 88.2% | 89.0% | 86.8% | 88.0% | 87.0% | 87.5% | 87.8% | 88.5% |
| Total Monomer | 66.2 | 127.1 | 125.3 | 125.3 | 70.9 | 70.9 | 58.3 | 58.3 |
| Weight (g) | | | | | | | | |
| Total Solvents (g) | 200 | 193 | 290 | 190 | 166 | 105 | 133 | 88 |

Lithographic printing plate precursors 1 to 9 were prepared as follows:

Bottom (inner imageable) layers (“BL”) 1 to 9 were prepared by coating a formulation prepared by dissolving 2.3 g of the Resin as shown in TABLE II, 0.15 g of IR Dye, 0.038 g of D11 in 37.5 g of Solvent Mixture A onto Substrate A and drying the coated formulation at 135° C. for 45 seconds to provide a dry coating weight for the inner imageable layer of 1.35 g/m².

Top (outer imageable) layer formulation 1 was prepared by dissolving 6.9 g of Polymer A, 0.59 g of polyurethane resin, 0.007 g of Ethyl Violet, 0.12 g of Byk® 307, and 0.35 g of Co1030 in 32 g of Solvent Mixture B.

The lithographic printing plate precursors 1 to 9 were prepared by coating the top layer formulation over the bottom layer formulations BL1-BL9 as indicated below in TABLE II to provide outer imageable layers each with a coating weight of about 0.58 g/m².

Each lithographic printing plate precursor was conditioned for 1 day at 50° C.

The following performance evaluations were made:

Photospeed and Ridges:

To assess the photospeed, each lithographic printing plate precursor was imaged with test patterns comprising solids and 8×8 checkerboard at 4 W to 16 W in steps of 1 W using a Kodak® Trendsetter 800 Quantum imagesetter (39 mJ/cm² to 102 mJ/cm²). The imaged precursor was developed in a Kodak T-HD Processor (Eastman Kodak) at 25° C. and 1500 mm/min using Developer A. The resulting lithographic printing plates were then evaluated for clear point and image attack, which is visible as ridges. All the lithographic printing plates showed a clear point between 65 mJ/cm² and 80 mJ/cm², and exhibited good image quality and resolution without ridges or any signs of peeling during development.

Solvent Resistance:

The solvent resistance was determined by measuring the gravimetric soak loss of the lithographic printing plate precursors after 5 minutes in the following solvent/water 80:20 mixtures of strong press room solvents, Butyl cellosolve (BC), dipropyleneglycol monomethyl ether (DPME), and diacetone alcohol (DAA).

The percentage loss after 5 minutes of soaking each precursor is recorded in TABLE II below. Resins 1-5 in the inner imageable layer generally provided very good resistance to the press room chemicals except when they had very low molecular weight in which case the resistance became worse.

Run Length:

The run lengths of lithographic printing plates obtained from lithographic printing plate precursors 1-11 were evaluated by looking for the image wear both in solids and screen areas and using the Sword Ultra lithographic printing plate as a reference. The run length achieved for each lithographic printing plate as a percentage compared to the reference lithographic printing plate is given in TABLE II below.

The relative molecular weights (Relative MW) of the Resins used in the inner imageable layer shown in TABLE II were measured by gel permeation chromatography using polystyrene standards.

TABLE II

| | Compara- | | Compara- | | Compara- | Compara- | Compara- | Compara- | Compara- |
|---|---|---|---|---|---|---|---|---|---|
| | tive | Invention | tive | Invention | tive | tive | tive | tive | tive |
| | Example 1 | Example 1 | Example 2 | Example 2 | Example 3 | Example 4 | Example 5 | Example 6 | Example 7 |
| | BL1 | BL2 | BL3 | BL4 | BL5 | BL6 | BL7 | BL8 | BL9 |
| | Resin | Resin | Resin | Resin | Resin | Resin | Resin | Resin | 70:30 Resin |
| | 1A | 1B | 2A | 2B | 2D | 3A | 4A | 4B | 1A:Resin 1B |
| Precursor | 1 | 2 | 3 | 4 | 5 | 6 | 7 | 8 | 9 |
| Relative | 47,925 | 264,830 | 49,267 | 329,482 | 50,294 | 54,053 | 32,232 | 200,474 | 112,997 |
| M_{w} | | | | | | | | | |
| Mₙ | 21,773 | 52,432 | 25,863 | 73,271 | 26,264 | 29,949 | 16,635 | 42,821 | 26,405 |
| Polydis- | 2.2 | 5.1 | 1.9 | 5.4 | 1.9 | 1.8 | 1.9 | 4.7 | 4.3 |
| persity | | | | | | | | | |
| M_{w}/Mₙ | | | | | | | | | |
| BC/H₂O | 0% | 0% | 6.4% | 2.4% | 4.0% | 5.0% | 7.7% | 6.9% | 0% |
| DPME/ | 0% | 0% | 14.0% | 2.5% | 1.0% | 2.0% | 73.1% | 4.4% | 0% |
| H₂O | | | | | | | | | |
| DAA/ | 4.0% | 1.0% | 55.1% | 3.1% | 2.0% | 3.0% | 87.7% | 2.5% | 1.0% |
| H₂O | | | | | | | | | |
| Run | 60% | 130% | 60% | 150% | 75% | 70% | 40% | 110% | 75% |
| length | | | | | | | | | |

The results shown in TABLE II indicate that the lithographic printing plate precursors all show good solvent resistance. However, only the lithographic printing plate precursors prepared according to the present invention in which the inner imageable layers comprise Resins having molecular weights of over 200,000 provided much higher run lengths compared to the use of polymers with lower molecular weight. Generally, high molecular weight resins in precursors can cause poor imaging speed and resolution as imaging layer dissolution in the developer can be slow and may result in plugged shadows in the screen areas. However, the Resins used according to the present invention do not cause these problems and imaging speed was not significantly reduced.

In Comparative Example 1, Resin 1A was prepared in a solution that contained a relatively low initial ethylenically unsaturated polymerizable monomer feed concentration. As a result, there was not enough chain transfer of growing free radicals to the polymer chain being formed during polymerization, leading to a lower molecular weight Resin 1A relative to higher molecular weight Resin 1B that was used in Invention Example 1. The use of the lower molecular weight resin led to lower run length for the Comparative Example 1 lithographic printing plate (Precursor 1) compared to the Invention Example 1 lithographic printing plate (Precursor 2).

Similarly, Resin 2A that was prepared with a low initial monomer feed concentration, had a lower molecular weight and the resulting Comparative Example 2 lithographic printing plate exhibited a lower run length (Precursor 3) compared to that the Inventive Example 2 lithographic printing plate (Precursor 4) that contained Resin 2B that was prepared with high initial monomer feed concentration.

In Comparative Examples 3 and 4, Resins 3A and 3B had a lower molecular weight than Resin 2B used in Invention Example 2 because of the absence of N-methoxymethyl methacrylamide as one of the ethylenically unsaturated polymerizable monomers used to prepare the polymer. The omission of this particular monomer made chain transfer from a growing free radical onto a polymer chain less likely. Moreover, the effect of ethylenically unsaturated polymerizable monomer concentration on Resins 3A and 3B was not as large as the effect on Resins 2A and 2B.

Thus, it was unexpectedly found that polymers lacking recurring units derived from N-methoxymethyl methacrylamide in the backbone under similar reaction conditions do not provide polymer molecular weights as high as polymers comprising such recurring units. It is believed that the N-methoxymethyl reactive recurring unit site enables branching under reaction conditions where the monomer feed relative to the solvent is high and where chain transfer can occur to the methoxymethyl functional groups. It is noted that in these cases a high polydispersity was provided, indicating high levels of branching, and this can provide desired results as described herein.

The effect of monomer feed concentration is also demonstrated in Comparative Example 5 containing Resin 4A in the precursor (Precursor 7) compared to Inventive Example 3 containing Resin 4B in the precursor (Precursor 8). The Comparative Example 5 lithographic printing plate containing Resin 4A (obtained with low initial monomer feed) exhibited inferior run length compared to the Invention Example 3 lithographic printing plate containing the high molecular weight Resin 4B (obtained with high initial monomer feed).

It is noted that in the inventive examples, the Resins used in the inner imageable layer had high polydispersity indicating high levels of branching. However, the Comparative Example 6 precursor contained a mixture of Resin 1A and Resin 1B to provide a mixture with high polydispersity and a low average molecular weight. The Comparative Example 6 lithographic printing plate exhibited poor run length indicating that it is not high polydispersity that provides good run length. The Resins prepared according to this invention under the desired monomer feed conditions led to polymers with high molecular weight with high branching indicated by high polydispersity, resulting in high run lengths in the resulting lithographic printing plates.

The invention has been described in detail with particular reference to certain preferred embodiments thereof, but it will be understood that variations and modifications can be effected within the spirit and scope of the invention.

1. A positive-working lithographic printing plate precursor comprising a substrate having a hydrophilic surface, and two or more layers disposed on the substrate, at least one of the layers comprising an infrared radiation absorber,
the two or more layers comprising:
an inner imageable layer disposed over the substrate, which inner imageable layer comprises one or more first polymeric binders that are present in a total amount of at least 50 weight % and up to and including 97 weight %, based on total inner imageable layer dry weight, and
an ink-receptive outer imageable layer disposed over the inner imageable layer, which ink-receptive outer imageable layer comprises one or more second polymeric binders that are different than the first polymeric binder,
wherein each of the one or more first polymeric binders has a weight average molecular weight of at least 200,000.

2. The precursor of claim 1, wherein each of the one or more first polymeric binders has a polydispersity of at least 4.

3. The precursor of claim 1, wherein each of the one or more first polymeric binders has a weight average molecular weight of at least 200,000 and up to and including 600,000, and a polydispersity of at least 4 and up to and including 10.5.

4. The precursor of claim 1, wherein each of one or more first polymeric binders has an acid number of at least 40 meq KOH/g of polymer, and at least one of the first polymeric binders comprises recurring units randomly distributed along the polymer chain, that are derived from one or more of the following groups of ethylenically unsaturated polymerizable monomers:
a) N-alkoxymethyl (meth)acrylamides or alkoxymethyl (alkyl)acrylates,
b) ethylenically unsaturated polymerizable monomers having pendant cyano groups,
c) ethylenically unsaturated polymerizable monomers having pendant 1H-tetrazole groups,
d) ethylenically unsaturated polymerizable monomers having one or more carboxy, sulfo, or phospho groups, and
e) ethylenically unsaturated polymerizable monomers represented by Structures (D1) through (D4): 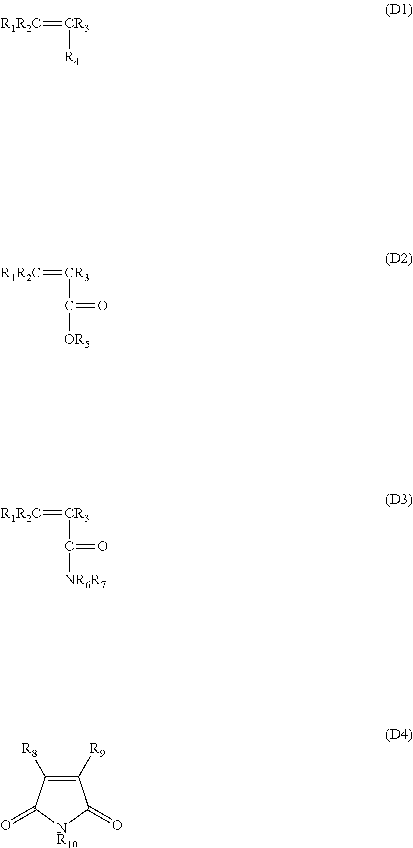
wherein R₁ and R₂ are independently hydrogen or alkyl, alkenyl, phenyl, halo, alkoxy, or acyloxy groups, or R₁ and R₂ together can form a cyclic ring with the carbon atom to which they are attached,
R₃ and R₄ are independently hydrogen or alkyl, phenyl, or halo groups,
R₅ is an alkyl, alkenyl, cycloalkyl, or phenyl group,
R₆ through R₉ are independently hydrogen or alkyl, alkenyl, phenyl, halo, alkoxy, acyl, or acyloxy groups, and
R₁₀ is hydrogen or an alkyl, phenyl, or hydroxy group.

5. The precursor of claim 4, wherein each of the one or more first polymeric binders has an acid number of from 65 meq KOH/g of polymer and up to and including 130 meq KOH/g of polymer, and at least one of the first polymeric binders comprises recurring units derived from at least:
an N-alkoxymethyl (meth)acrylamide or alkoxymethyl (alkyl)acrylate, or
an ethylenically unsaturated polymerizable monomer having pendant 1H-tetrazole groups.

6. The precursor of claim 5, wherein at least one of the first polymeric binders comprises at least 5 weight % and up to and including 30 weight % of recurring derived from one or more N-alkoxymethyl (meth)acrylamides, based on the total polymer recurring units.

7. The precursor of claim 4, wherein at least one first polymeric binders comprises recurring units derived from both:
an N-alkoxymethyl (meth)acrylamide or alkoxymethyl (alkyl)acrylate, and
an ethylenically unsaturated polymerizable monomer having pendant 1H-tetrazole groups.

8. The precursor of claim 1, wherein the ink-receptive outer imageable layer comprises a second polymeric binder selected from the group consisting of: at least one acidic polyurethane, at least one carboxy-functionalized phenolic resin, and a combination of at least one acidic polyurethane, at least one carboxy-functionalized phenolic resin.

9. The precursor of claim 1, wherein the infrared radiation absorber is present in an amount of at least 0.5 weight % and up to and including 30 weight %.

10. The precursor of claim 1, wherein the infrared radiation absorber is present only in the inner imageable layer.

11. The precursor of claim 1, when the inner imageable layer and the ink-receptive outer imageable layer are exposed to infrared radiation, they become more removable in a developer having a pH of 12.5 or less than before exposure to infrared radiation.

12. The precursor of claim 1, wherein each of the one or more first polymeric binders has a solubility of less than 100 mg/g when agitated for 24 hours at 25° C. in either an 80 weight % aqueous solution of 2-butoxyethanol or an 80 weight % aqueous solution of diacetone alcohol.

13. The precursor of claim 1, wherein:
1) each of the one or more first polymeric binders has a weight average molecular weight of at least 200,000 and up to and including 600,000, and a polydispersity of at least 4 and up to and including 10.5,
2) each of one or more first polymeric binders has an acid number of at least 40 meq KOH/g of polymer, and at least one of the first polymeric binders comprises recurring units randomly distributed along the polymer chain, that are derived from one or more of the following groups of ethylenically unsaturated polymerizable monomers:
a) N-alkoxymethyl (meth)acrylamides or alkoxymethyl (alkyl)acrylates,
b) ethylenically unsaturated polymerizable monomers having pendant cyano groups,
c) ethylenically unsaturated polymerizable monomers having pendant 1H-tetrazole groups,
d) ethylenically unsaturated polymerizable monomers having one or more carboxy, sulfo, or phospho groups, and
e) ethylenically unsaturated polymerizable monomers represented by Structures (D1) through (D4): 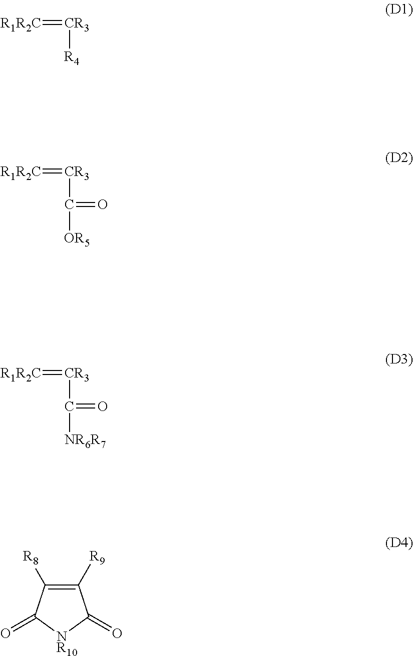
wherein R₁ and R₂ are independently hydrogen or alkyl, alkenyl, phenyl, halo, alkoxy, or acyloxy groups, or R₁ and R₂ together can form a cyclic ring with the carbon atom to which they are attached,
R₃ and R₄ are independently hydrogen or alkyl, phenyl, or halo groups,
R₅ is an alkyl, alkenyl, cycloalkyl, or phenyl group,
R₆ through R₉ are independently hydrogen or alkyl, alkenyl, phenyl, halo, alkoxy, acyl, or acyloxy groups, and
R₁₀ is hydrogen or an alkyl, phenyl, or hydroxy group.
3) the ink-receptive outer imageable layer comprises at least two second polymeric binders, at least one of which is an acidic polyurethane and at least another of which is a carboxy-functionalized phenolic resin,
4) the infrared radiation absorber is present in an amount of at least 0.5 weight % and up to and including 25 weight %,
5) the infrared radiation absorber is present only in the inner imageable layer,
6) when the inner imageable layer and outer imageable layer are exposed to infrared radiation, they become more removable in a developer having a pH of 12.5 or less than before exposure to infrared radiation, and
7) the substrate is an aluminum-containing substrate.

14. A method for making a lithographic printing plate, comprising:
imagewise exposing the positive-working lithographic printing plate precursor of claim 1 to infrared radiation, thereby forming an imaged precursor having exposed and non-exposed regions in the inner imageable layer and the ink-receptive outer imageable layer, and
processing the imaged precursor to remove the exposed regions of the inner imageable layer and the ink-receptive outer imageable layer and to form a lithographic printing plate.

15. The method of claim 14, wherein there are no intermediate treatment of the precursor between the imagewise exposing and the processing.

16. The method of claim 14, wherein the processing is carried out using a processing solution having a pH of at least 6 and up to and including 12.5.

17. The method of claim 14, wherein the processing is carried out using a processing solution having a pH of at least 7 and up to and including 13.5.

18. The method of claim 14, wherein, after the imagewise exposing and processing, the lithographic printing plate is baked at a temperature above room temperature for at least 1 minute, or the lithographic printing plate is uniformly exposed to infrared radiation.

19. A method for making a lithographic printing plate, comprising:
imagewise exposing the positive-working lithographic printing plate precursor of claim 13 to infrared radiation, thereby forming an imaged precursor having exposed and non-exposed regions the inner imageable layer and the ink-receptive outer imageable layer, and
processing the imaged precursor to remove the exposed regions of the inner imageable layer and the ink-receptive outer imageable layer and to form a lithographic printing plate.

20. A lithographic printing plate comprising a substrate having a hydrophilic surface, and two or more layers disposed on the substrate, at least one of the layers comprising an infrared radiation absorber,
the two or more layers comprising:
an inner imageable layer disposed over the substrate, which inner imageable layer comprises one or more first polymeric binders that are present in a total amount of at least 50 weight % and up to and including 97 weight %, based on total inner imageable layer dry weight, and
an ink-receptive outer imageable layer disposed over the inner imageable layer, which ink-receptive outer imageable layer comprises one or more second polymeric binders that are different than the first polymeric binder, wherein each of the one or more first polymeric binders has a weight average molecular weight of at least 200,000 and a polydispersity of at least 4, and
wherein the inner imageable layer and the ink-receptive outer imageable layer are present on the substrate only in non-exposed regions while the inner imageable layer and the ink-receptive outer imageable layer have been removed in exposed regions to uncover the hydrophilic surface of the substrate.
